(19) United States
(12) Patent Application Publication
(10) Pub. No.: US 2002/0017454 A1
(43) Pub. Date: Feb. 14, 2002

(54) Method and system for improving the effectiveness of intraocular lenses by the application of gas cluster ion beam technology

(75) Inventor: Allen R. Kirkpatrick, Lexington, MA (US)

Correspondence Address: PERKINS, SMITH & COHEN LLP, ONE BEACON STREET, 30TH FLOOR, BOSTON, MA, 02108, US

(73) Assignee: Epion Corporation

(21) Appl. No.: 09/901,202

(22) Filed: Jul. 9, 2001

Related U.S. Application Data
(60) Provisional application No. 60/217,198, filed on Jul. 10, 2000.

(51) Int. Cl. C23F 1/00; C23C 14/32

(52) U.S. Cl. 204/192.34; 118/723 CB; 204/298.36; 216/66; 156/345

(57) ABSTRACT

Atomic level surface smoothing utilizing GCIB to smooth and round the IOL's outer edges to reduce the “edge effect” and its resultant glare. In addition, the present invention provides, atomic level surface smoothing utilizing GCIB to smooth the IOL's posterior and/or anterior surfaces to improve the adhesion of the IOL to the capsule, preventing cell in-growth and their resultant secondary cataract. The GCIB smoothed surfaces will also reduce inflammatory response by reducing foreign particles on the surface and by reducing the micro-roughness normally inherent on the IOL surface.

### CROSS REFERENCE TO RELATED APPLICATIONS

This application claims priority of U.S. provisional application serial No. 60/217,198 entitled “Method and System for Improving the Effectiveness of Intraocular Lenses by the Application of Gas Cluster Ion Beam Technology”, filed Jul. 10, 2000, the provisional application being incorporated herein by reference.

### FIELD OF THE INVENTION

This invention relates generally to medical devices such as lenses and, more particularly to a method and system for smoothing intraocular lenses using gas cluster ion beam technology.

### BACKGROUND OF THE INVENTION

Significant post-operative vision-disturbing complications remain frequent with the use of intraocular lenses (IOL) in cataract surgery. Post-operative clouding of an IOL, also called a secondary cataract, is the most common complication, occurring in 30% to 50% of all IOL implants. Secondary cataracts are due to posterior migration of the normal lens epithelium cells from the equatorial region into the space between the original lens capsule and the IOL.

Also, acute or chronic inflammatory reactions may occur due to biocompatibility issues with IOLs that can lead to the formation of reactive components, which in turn promote inflammatory reactions (e.g., increased vascular permeability, chemotaxis, and augmented phagocytosis). Additionally, some IOL patients suffer from the “edge effect,” a leading cause of explants in intraocular lenses. The “edge effect” is a result of squared rough outer edges that scatter light reflected off the edges. The light is not focused onto the retina and leads to severe complaints of glare. Despite the development of sophisticated techniques for lens extraction and extensive research on replacement lens materials, the significant post-operative vision-disturbing complications detailed above remain frequent with cataract surgery.

It is therefore an object of this invention to provide an atomic level surface smoothing of intraocular lenses.

It is a further object of this invention to provide surface modification of intraocular lenses by gas cluster ion beams to alleviate vision disturbing complications and patient suffering resulting from the use of such lenses.

### SUMMARY OF THE INVENTION

The objects set forth above as well as further and other objects and advantages of the present invention are achieved by the invention described hereinbelow.

The present invention provides surface modification of intraocular lenses (IOL) utilizing GCIB to smooth the posterior and anterior surfaces of an IOL as well as its edges. This smoothing will prevent the migration of epithelium cells and improve the biocompatibility of the lens surface, reducing post-operative complications. The reduction of these post-operative complications provides substantial costs savings and reduces patient suffering.

The present invention provides atomic level surface smoothing utilizing GCIB to smooth and round the IOL's outer edges to reduce the “edge effect” and its resultant glare. In addition, the present invention provides atomic level surface smoothing utilizing GCIB to smooth the IOL's posterior and/or anterior surfaces to improve the adhesion of the IOL to the capsule, preventing cell in-growth and their resultant secondary cataract. The GCIB smoothed surfaces will also reduce inflammatory response by reducing foreign particles on the surface and by reducing the micro-roughness normally inherent on the IOL surface.

For a better understanding of the present invention, together with other and further objects thereof, reference is made to the accompanying drawings and detailed description and its scope will be pointed out in the appended claims.

### BRIEF DESCRIPTION OF THE DRAWINGS

FIG. 1 is a schematic view of a gas cluster ion beam processing system of the present invention;

FIG. 2 is an exploded view of a portion of the gas cluster ion beam processing system showing the workpiece holder;

FIG. 3 is an atomic force microscope image showing the surface of an IOL before GCIB processing; and

FIG. 4 is an atomic force microscope image showing the surface of an IOL after GCIB processing.

### DETAILED DESCRIPTION OF THE PREFERRED METHODS AND EMBODIMENTS

Beams of energetic ions, electrically charged atoms or molecules accelerated through high voltages under vacuum, are widely utilized to form semiconductor device junctions, to smooth surfaces by sputtering, and to enhance the properties of thin films. Gas cluster ions are formed from large numbers of weakly bound atoms or molecules sharing common electrical charges and accelerated together through high voltages to have high total energies. Cluster ions disintegrate upon impact and the total energy of the cluster is shared among the constituent atoms. Because of this energy sharing, the atoms are individually much less energetic than the case of conventional ions or ions not clustered together and, as a result, the atoms penetrate to much shorter depths. Surface sputtering effects are orders of magnitude stronger than corresponding effects produced by conventional ions, thereby making important microscale surface smoothing effects possible that are not possible in any other way.

The concept of gas cluster ion beam (GCIB) processing has only emerged over the past decade. Using a GCIB for dry etching, cleaning, and smoothing of materials is known in the art and has been described, for example, by Deguchi, et al. in U.S. Pat. No. 5,814,194, “Substrate Surface Treatment Method”, 1998. Because ionized clusters containing on the order of thousands of gas atoms or molecules may be formed and accelerated to modest energies on the order of a few thousands of electron volts, individual atoms or molecules in the clusters may each only have an average energy on the order of a few electron volts. It is known from the teachings of Yamada in, for example, U.S. Pat. No. 5,459,326, that such individual atoms are not energetic enough to significantly penetrate a surface to cause the residual sub-surface damage typically associated with plasma polishing. Nevertheless, the clusters themselves are sufficiently energetic (some thousands of electron volts) to effectively etch, smooth, or clean hard surfaces.

Because the energies of individual atoms within a gas cluster ion are very small, typically a few eV, the atoms penetrate through only a few atomic layers, at most, of a target surface during impact. This shallow penetration of the impacting atoms means all of the energy carried by the entire cluster ion is consequently dissipated in an extremely small volume in the top surface layer during a period of 10⁻¹² seconds. This is different from the case of ion implantation which is normally done with conventional ions and where the intent is to penetrate into the material, sometimes penetrating several thousand angstroms, to produce changes in the surface properties of the material. Because of the high total energy of the cluster ion and extremely small interaction volume, the deposited energy density at the impact site is far greater than in the case of bombardment by conventional ions.

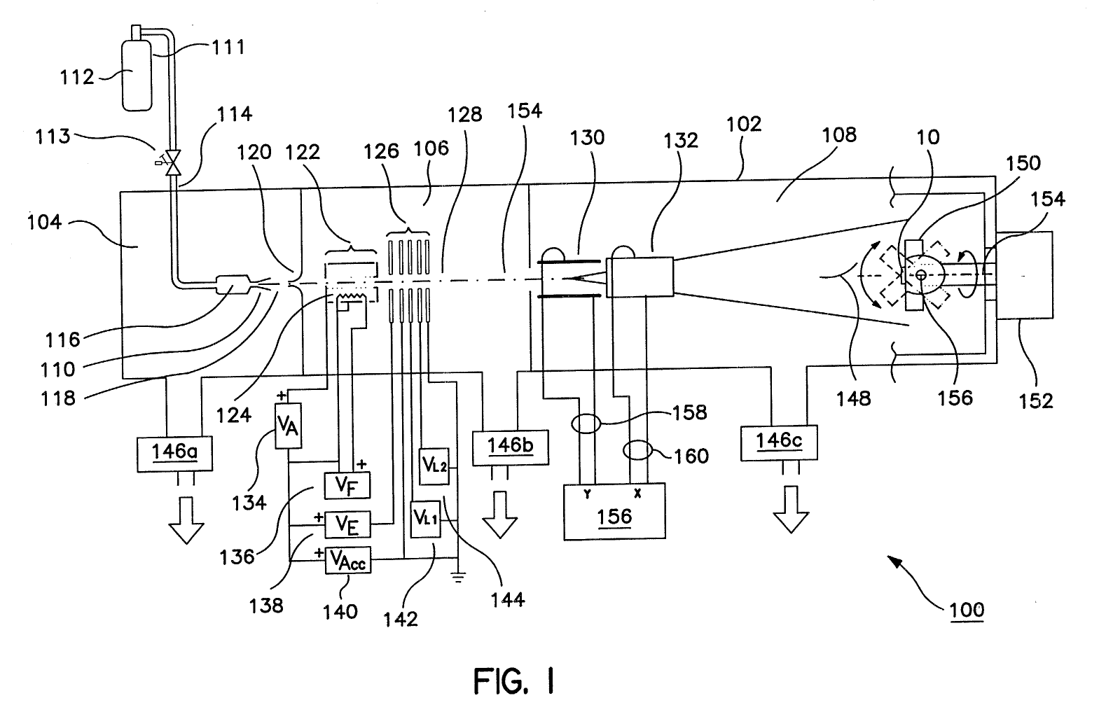

Reference is now made to FIG. 1 of the drawings which shows the gas cluster ion beam (GCIB) processor 100 of this invention utilized for the surface smoothing of an IOL 10. Although not limited to the specific components described herein, the processor 100 is made up of a vacuum vessel 102 which is divided into three communicating chambers, a source chamber 104, an ionization/acceleration chamber 106, and a processing chamber 108 which includes therein a uniquely designed workpiece holder 150 capable of positioning the IOL 10 for uniform smoothing by a gas cluster ion beam.

During the smoothing method of this invention, the three chambers are evacuated to suitable operating pressures by vacuum pumping systems 146a, 146b, and 146c, respectively. A condensable source gas 112 (for example argon or N2) stored in a cylinder 111 is admitted under pressure through gas metering valve 113 and gas feed tube 114 into stagnation chamber 116 and is ejected into the substantially lower pressure vacuum through a properly shaped nozzle 110, resulting in a supersonic gas jet 118. Cooling, which results from the expansion in the jet, causes a portion of the gas jet 118 to condense into clusters, each consisting of from several to several thousand weakly bound atoms or molecules. A gas skimmer aperture 120 partially separates the gas molecules that have not condensed into a cluster jet from the cluster jet so as to minimize pressure in the downstream regions where such higher pressures would be detrimental (e.g., ionizer 122, high voltage electrodes 126, and process chamber 108). Suitable condensable source gases 112 include, but are not necessarily limited to argon, nitrogen, carbon dioxide, oxygen, and other gases.

After the supersonic gas jet 118 containing gas clusters has been formed, the clusters are ionized in an ionizer 122. The ionizer 122 is typically an electron impact ionizer that produces thermoelectrons from one or more incandescent filaments 124 and accelerates and directs the electrons causing them to collide with the gas clusters in the gas jet 118, where the jet passes through the ionizer 122. The electron impact ejects electrons from the clusters, causing a portion the clusters to become positively ionized. A set of suitably biased high voltage electrodes 126 extracts the cluster ions from the ionizer 122, forming a beam, then accelerates the cluster ions to a desired energy (typically from 1 keV to several tens of keV) and focuses them to form a GCIB 128 having an initial trajectory 154. Filament power supply 136 provides voltage V_{F} to heat the ionizer filament 124. Anode power supply 134 provides voltage V_{A} to accelerate thermoelectrons emitted from filament 124 to cause them to bombard the cluster containing gas jet 118 to produce ions. Extraction power supply 138 provides voltage V_{E} to bias a high voltage electrode to extract ions from the ionizing region of ionizer 122 and to form a GCIB 128. Accelerator power supply 140 provides voltage V_{Acc} to bias a high voltage electrode with respect to the ionizer 122 so as to result in a total GCIB acceleration energy equal to V_{Acc} electron volts (eV). One or more lens power supplies (142 and 144, for example) may be provided to bias high voltage electrodes with potentials (V_{L1} and V_{L2} for example) to focus the GCIB 128.

With the present invention, an intraocular lens (IOL) 10 to be processed by the GCIB processor 100 is held on a workpiece holder 150, disposed in the path of the GCIB 128. In order for the uniform smoothing of the IOL 10 to take place, the workpiece holder 150 is designed in a manner set forth below to appropriately manipulate the lens 10 in a specific way.

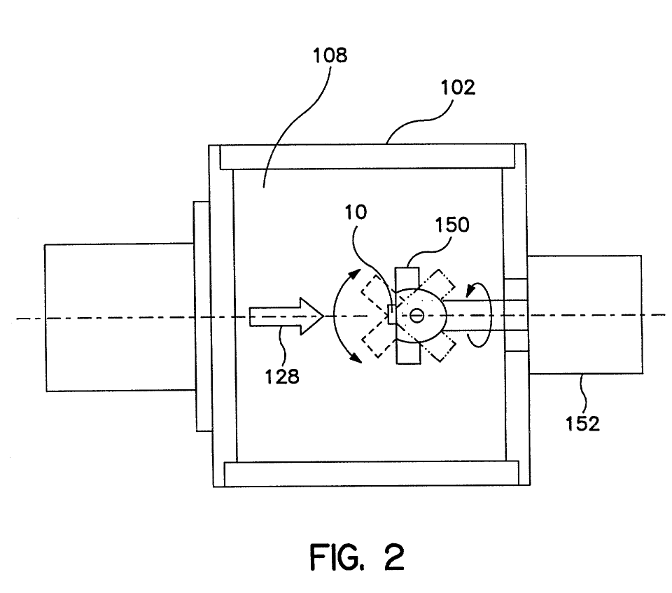

Referring also to FIG. 2, the IOL surfaces that are non-planar must remain oriented within a specific angle tolerance with respect to the normal beam incidence to obtain paramount smoothing of the IOL 10 utilizing GCIB. This requires a lens fixture or workpiece holder 150 with the ability to be fully articulated to orient all non-planar surfaces to be modified within that angle tolerance at a constant exposure level for process optimization and uniformity. Any lens 10 containing surfaces that would be exposed to the process beam at angles of greater than +/−15 degrees from normal incidence requires manipulation. More specifically, when smoothing an IOL 10, the workpiece holder 150 is rotated and articulated by a mechanism 152 located at the end of the GCIB processor 100. The articulation/rotation mechanism 152 preferably permits 360 degrees of device rotation about longitudinal axis 154 and sufficient device articulation about an axis 156 perpendicular to axis 154 to maintain the lens 10 surface to within +/−15 degrees from normal beam incidence.

Under certain conditions, depending upon the size of the IOL 10, a scanning system may be desirable to produce uniform smoothness. Although not necessary for GCIB processing, two pairs of orthogonally oriented electrostatic scan plates 130 and 132 may be utilized to produce a raster or other scanning pattern over an extended processing area. When such beam scanning is performed, a scan generator 156 provides X-axis and Y-axis scanning signal voltages to the pairs of scan plates 130 and 132 through lead pairs 158 and 160 respectively. The scanning signal voltages are commonly triangular waves of different frequencies that cause the GCIB 128 to be converted into a scanned GCIB 148, which scans the entire surface of the IOL 10.

When beam scanning over an extended region is not desired, processing is generally confined to a region that is defined by the diameter of the beam. The diameter of the beam at the 's surface can be set by selecting the voltages (V_{L1} and/or V_{L2}) of one or more lens power supplies (142 and 144 shown for example) to provide the desired beam diameter at the workpiece.

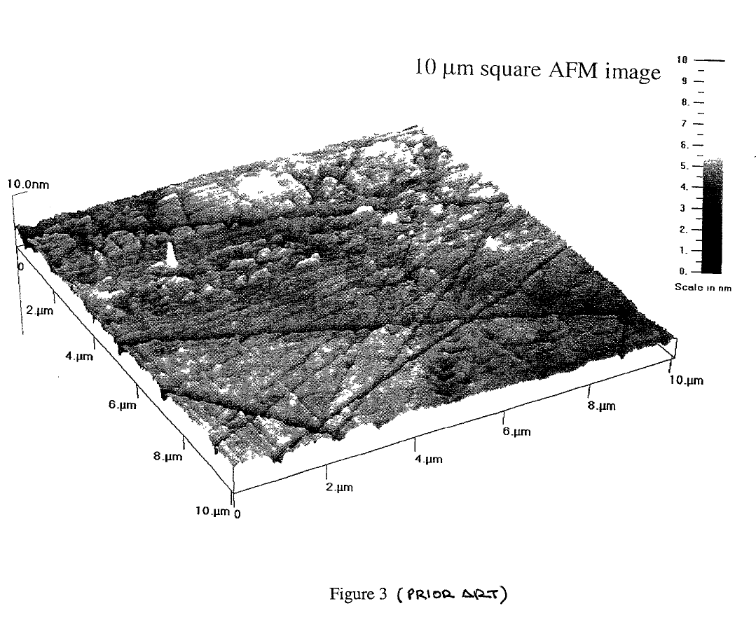

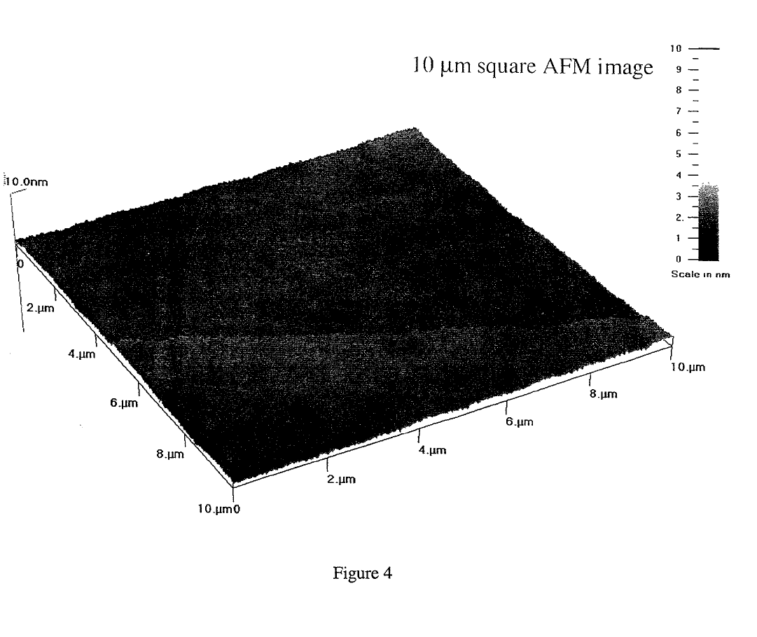

As the atomic force microscope (AFM) images shown in FIGS. 3 and 4 demonstrate, it is possible to improve the surface smoothness on intraocular lenses 10 utilizing the present invention. FIG. 3 shows an IOL 10 surface composed of acrylic before GCIB treatment with gross surface micro-roughness. The surface roughness measured an Rₐ of 46.5 angstroms and an R_{RMS} of 59.4 angstroms. These irregularities highlight the surface micro-roughness problem at the cellular level where post-operative complications begin. FIG. 4 shows an IOL 10 surface composed of acrylic after GCIB processing where the surface micro-roughness has been reduced without any measurable structural change to the integrity of the lens itself. The post-GCIB surface roughness measured an Rₐ of 22.6 angstroms and an R_{RMS} of 28.9 angstroms.

Although the invention has been described with respect to various embodiments, it should be realized this invention is also capable of a wide variety of further and other embodiments within the spirit and scope of the appended claims.

What is claimed is:

1. An apparatus for modifying the surface of an intraocular lens by gas cluster ion beam processing comprising:
a vacuum vessel;
a gas cluster ion beam source operably associated with the vacuum vessel for producing a gas cluster ion beam;
an accelerator for accelerating the gas cluster ion beam along a path;
an intraocular lens holder disposed substantially along a longitudinal axis within the gas cluster ion beam path, said intraocular lens holder positioning the intraocular lens for gas cluster ion beam processing;
repositioning means operably connected to said intraocular lens holder for rotating said intraocular lens holder and the intaocular lens about said longitudinal axis and articulating the intraocular lens holder and the intaocular lens about an axis perpendicular to said longitudinal axis.

2. The apparatus of claim 1, wherein the repositioning means articulates multiple regions of the intraocular lens to intercept the gas cluster ion beam path at an angle of beam incidence that is substantially normal to the intraocular lens.

3. The apparatus of claim 2, wherein the angle of beam incidence is within +/−15 degrees of normal.

4. The apparatus of claim 1 further comprising scanning means for scanning the gas cluster ion beam and the intraocular lens relative to each other.

5. The apparatus of claim 1 wherein the gas cluster ion beam processing smoothes the surface of the intraocular lens.

6. The apparatus of claim 1 wherein the gas cluster ion beam processing smoothes the edges of the intraocular lens.

7. A method for modifying the surface of an introcular lens by gas cluster ion beam processing to improve a surface thereof, comprising the steps of:
forming an inert gas cluster ion beam in a vacuum chamber;
accelerating the gas cluster ion beam;
positioning a surface of the introcular lens in the vacuum chamber to receive the gas cluster ion beam for processing; and
irradiating the surface with a predetermined dose of gas cluster ions having a predetermined energy.

8. The method of claim 7, further comprising the step of rotating or articulating the surgical implant to smooth the surface of the intraocular lens.

9. The method of claim 7, further comprising the step of rotating or articulating the intraocular lens to smooth the edges of the intraocular lens.

10. The method of claims 7, further comprising the steps of:
rotating or repositioning the surgical implant to process regions of the intraocular lens; and
subjecting the the intraocular lens with a gas cluster ion beam incident substantially normal to the the intraocular lens.
